(19) United States
(12) Patent Application Publication
(10) Pub. No.: US 2025/0006691 A1
(43) Pub. Date: Jan. 2, 2025

(54) COMPLIANT INSERTS FOR PIN DIPPING PROCESSES

(71) Applicant: Intel Corporation, Santa Clara, CA (US)

(72) Inventors: George Robinson, Chandler, AZ (US); Mohamed Elhebeary, Chandler, AZ (US); Divya Jain, Mesa, AZ (US); Viet Chau, Vancouver, WA (US); Zewei Wang, Chandler, AZ (US); Mukund Ayalasomayajula, Chandler, AZ (US); Suraj Maganty, Chandler, AZ (US); Tingting Gao, Chandler, AZ (US); Andrew Wayne Carlson, Chandler, AZ (US); Khalid Mohammad Abdelaziz, Chandler, AZ (US); Craig Jerome Madison, Gilbert, AZ (US); Edvin Cetegen, Chandler, AZ (US); Joseph Petrini, Gilbert, AZ (US)

(21) Appl. No.: 18/345,695

(22) Filed: Jun. 30, 2023

(51) Int. Cl. H01L 23/00

(52) U.S. Cl. CPC H01L 24/81; H01L 2224/81001; H01L 2224/81024; H01L 2224/81911

(57) ABSTRACT

Compliant inserts for pin dipping processes are disclosed herein. An example apparatus disclosed herein includes a pin array to transfer material to a package substrate of an integrated circuit package, a cover plate, an elastic insert to be disposed between the cover plate and the pin array.

### FIELD OF THE DISCLOSURE

This disclosure relates generally to package substrates of integrated circuits and, more particularly, to compliant inserts for pin dipping processes.

### BACKGROUND

In many integrated circuit packages, one or more semiconductor dies are mechanically and electrically coupled to an underlying package substrate. Frequently, the coupling of a die to an underlying substrate is achieved by aligning and connecting metal bumps fabricated on a surface of the die with corresponding pads and/or bumps on a facing surface of the package substrate. Such connections are often referred to as first level interconnects (FLI). Connections between the package substrate and a printed circuit board are often referred to as second level interconnects (SLI). Frequently, second level interconnects are implemented via a ball grid array (BGA). Ball grid arrays are formed via solder balls on the pads of the package substrate. During operation, these solder balls transfer electrical signals between the package substrate and the printed circuit board.

### BRIEF DESCRIPTION OF THE DRAWINGS

FIG. 1 is a perspective exploded view of an example pin assembly implemented in accordance with the teachings of this disclosure.

FIG. 2 is a perspective detail view of a portion of the assembly of FIG. 1.

FIG. 3A is a top view of an example tooling rig including a plurality of assemblies implemented in accordance with teachings of this disclosure.

FIG. 3B is a bottom view of an example tooling rig including a plurality of assemblies implemented in accordance with teachings of this disclosure.

FIG. 3C is a side view of an example tooling rig including a plurality of assemblies implemented in accordance with teachings of this disclosure.

FIG. 4 is a top detail view of a portion of an assembly of FIGS. 3A-3C.

FIG. 5 is a top detail view of another portion of an assembly of FIGS. 3A-3C.

FIG. 6A is a schematic illustration of the operation of a portion of the assembly of FIGS. 1 and 2 at a first position.

FIG. 6B is a schematic illustration of the operation of a portion of the assembly of FIGS. 1 and 2 at a second position.

FIG. 6C is a schematic illustration of the operation of a portion of the assembly of FIGS. 1 and 2 at a third position.

The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular. In general, the same reference numbers will be used throughout the drawing(s) and accompanying written description to refer to the same or like parts. As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another. Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component. As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween. As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name. As used herein, “approximately” and “about” refer to dimensions that may not be exact due to manufacturing tolerances and/or other real world imperfections.

### DETAILED DESCRIPTION

Planar mounting, also called surface mounting, refers to methods of coupling compute components to printed circuit boards. One type of surface mounting is via a ball grid array, which is often used to connect an integrated circuit (IC) package of a compute component to a printed circuit board (e.g., second level interconnects, etc.). Ball grid arrays are a grid of solder balls that are formed on conductive pads of the package substrate of the IC package. Frequently, these soldier balls are retrained to the pad via flux deposited on the pads prior to the deposition of the solder balls.

Connections between the package substrate and a printed circuit board are often referred to as second level interconnects (SLI). Frequently, second level interconnects are implemented via a ball grid array (BGA). Ball grid arrays are formed via solder balls on the pads of the package substrate of an IC package. During operation, these solder balls transfer electrical signals between the IC package and the printed circuit board. A ball grid array (BGA) is a type of surface mount packaging that is used for integrated circuits. Balls of solder are first soldered to the pads on the surface mount package. These balls of solder may conduct electrical signals from the integrated circuit to the printed circuit board (PCB) on which the BGA is placed. The solder balls may be held in place with flux until soldering occurs. Flux is deposited by dipping a grid of pins in a source of flux and then pressing the pins onto the substrate to deposit the flux thereon. If the flux is not transferred to the pad, a solder ball cannot be connected thereto, which reduces the number of connections provided by the BGA and can render the corresponding package inoperable.

In recent years, package substrates have become thinner and/or coreless. In some examples, during the manufacturing of IC packages, the packages are subject to a wide range of temperatures (e.g., during a reflow process to attach a semiconductor die to the package substrate, etc.). In some such examples, mismatches in coefficients of thermal expansion (CTE) between components of the package (e.g., a mismatch between the CTE of the silicon die and the organic substrate, etc.) can cause warpage in the package (including the package substrate). Such warpage is often more severe for packages with thin and/or coreless package substrates. As described above, flux can be transferred onto package substrates via an array of pins pressed onto the grid of pads. Warped package substrates can have lower contact points in the middle of the substrate. Prior tooling assemblies including such flux transfer pins are rigid, which can prevent contact between some of these pins and the lower contact points. In some examples, if the warpage of the package substrate prevents the deposition of flux on one or more of the pads, a soldier ball cannot be deposited on the pad, which can compromise the BGA and can cause the entire package to be reprocessed, rejected, and/or scrapped.

Examples disclosed herein overcome the above-noted deficiencies via assemblies with compliant inserts that facilitate the contact of flux transfer pins and warped package substrates. Examples disclosed herein include pin assemblies with inserts composed of a flexible and compliant material. In some such examples disclosed herein, compliant inserts facilitate the deflection of the pin assemblies so depressed regions of the warped package substrates can be contacted by the pins of the pin assemblies. In some examples disclosed herein, the inserts can be preloaded in compression in the pin assemblies to increase the spring back of the pin assembly to an unload position. In some examples disclosed herein, the pin assemblies further include one or more interface plates disposed between the compliant insert and the pins. In some such examples disclosed herein, the interface plates are composed of an elastic strong material, such as stainless steel, to increase the spring back of the pin assembly to an unload position. The compliant inserts and/or the interface plates of examples disclosed herein cause the pin assemblies to deflect and conform with the warpage of package substrates of IC packages. Some examples disclosed herein include cutouts, holes, and openings disposed in the frames, cover plates, and/or tooling rigs to enable the flow of cleaning fluid to remove the residue flux therefrom.

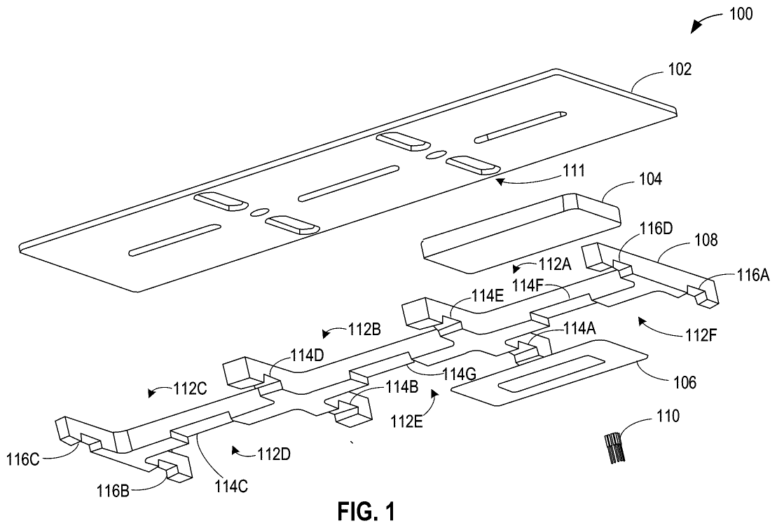

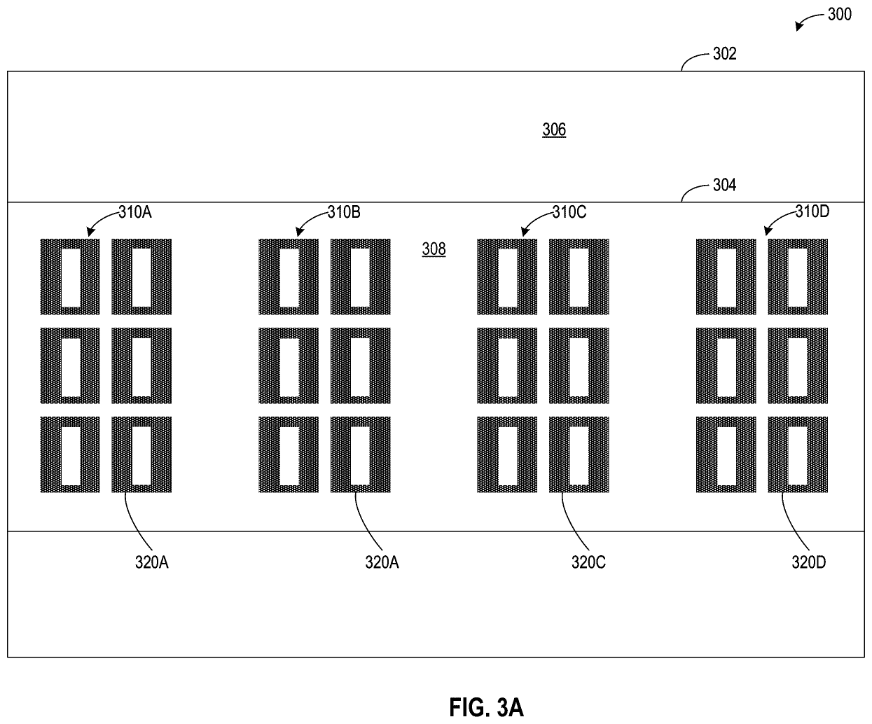

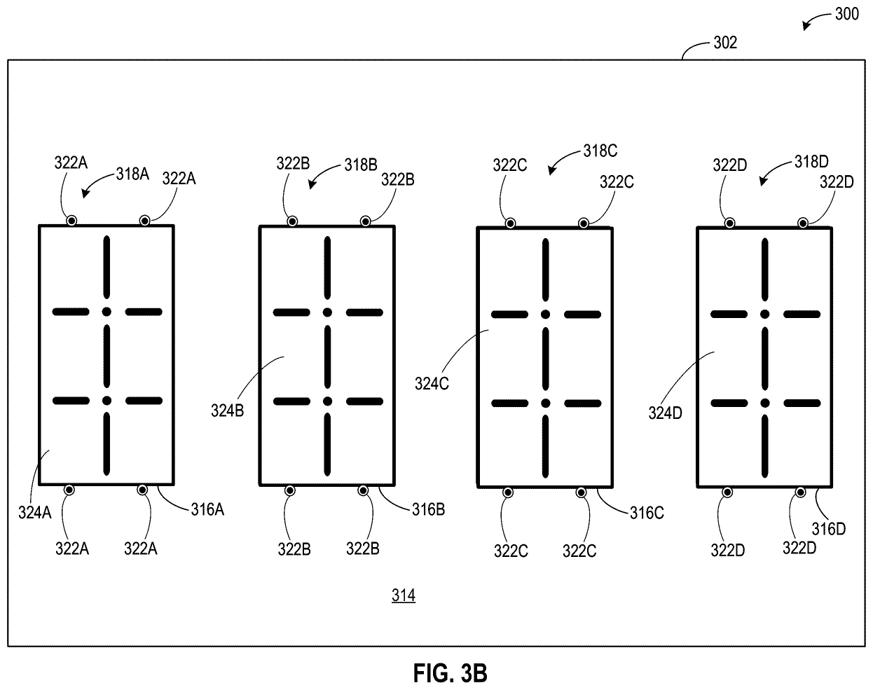

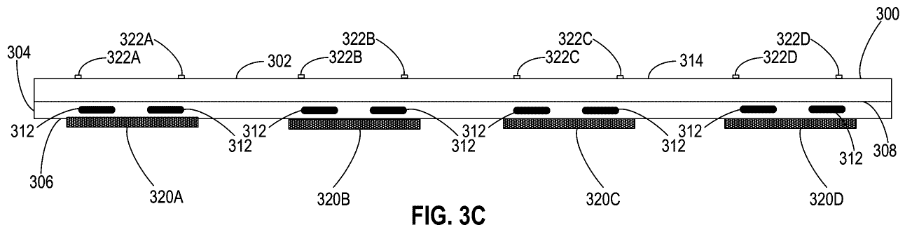

FIG. 1 is an exploded view of an example assembly 100 implemented in accordance with teachings of this disclosure. In the illustrated example of FIG. 1, the assembly 100 includes an example cover plate 102, an example compliant insert 104, an example interface plate 106, an example frame 108, and example pins 110 (e.g., a pin array, etc.). The example assembly 100 is an apparatus for transferring flux between a flux source and the pads of a package substrate for second level interconnects. In some examples, the assembly 100 can be used in a tooling rig such that the pins 110 of the assembly 100 extend through a plurality of openings in a bottom surface of the tooling rig (e.g., the tooling rig 300 of FIG. 3). In some such examples, the cover plate 102 of the assembly 100 is coupled to the tooling rig via one or more fasteners. In some such examples, the coupling of the cover plate 102 to the tooling rig retains the components of the assembly 100 in compression between the bottom surface of the tooling rig and the cover plate 102. An example tooling rig that can be used with the assembly 100 is described below in conjunction with FIG. 3.

The cover plate 102 is a mechanical component that retains the assembly 100 in a tooling rig. In the illustrated example of FIG. 1, the cover plate 102 includes example holes 111. In some examples, the holes 111 permit the movement of cleaning fluid to move through the assembly 100 and remove residue therefrom. In the illustrated example of FIG. 1, the holes 111 are aligned with the frame 108. In other examples, the holes 111 can have any other suitable position on the cover plate 102. In other examples, some or all of the holes 111 can be absent.

The compliant insert 104 is a resiliently compressible component disposed between the interface plate 106 and the example frame 108. The compliant insert 104 is an elastic insert. In the illustrated example of FIG. 1, the compliant insert 104 abuts the interface plate 106, the example frame 108, and the cover plate 102. In other examples, one or more additional components can be disposed between the compliant insert 104 and one and/or both of the interface plate 106 and the example frame 108. In some examples, the compliant insert 104 can be composed of silicone foam. In other examples, the compliant insert 104 can be composed of any other suitable elastic/compressible material (e.g., an open cell foam, a closed cell foam, etc.). Additionally or alternatively, the compliant insert 104 is composed of material that is resistant to one or more cleaning fluids (e.g., deionized water, acetone, isopropyl, etc.) that can be used to remove residue (e.g., residue flux, etc.) from the assembly 100. In some examples, to mitigate creep and/or fatigue of the compliant insert 104, assembly 100 can be maintained at an ambient temperature during operation, and/or the cleaning fluid used to clean the assembly 100 can be kept below 120 degrees Celsius.

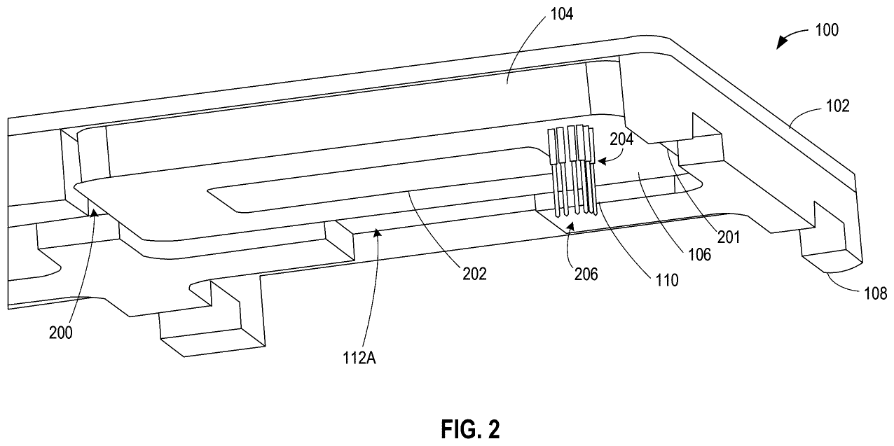

The interface plate 106 is a mechanical component disposed between the compliant insert 104 and the pins 110 (e.g., the interface plate 106 is means for interfacing between the compliant insert 104 and the pins 110, etc.). In some examples, during operation, the interface plate 106 functions as a spring that transfers force between the cover plate 102 (e.g., applied by a press, etc.) and the pins 110. In some such examples, the interface plate 106 facilitates contact between the pins 110 and the pads of a package substrate. In some such examples, the interface plate 106 is composed of a material and has a geometry that facilitates compliance with the warpage profile of the substrate. For example, the interface plate 106 can be composed of one or more elastic metal(s) (e.g., stainless steel such as SS304, spring steel, titanium, brass, nickel alloys, bronze, etc.) and/or any other suitably elastic, resilient, and strong material. In some examples, the interface plate 106 has a thickness that enables the elastic deformation thereof during the operation of the assembly 100. In some such examples, the interface plate 106 can have a thickness between 100 micrometers and 150 micrometers. In some examples, the interface plate 106 prevents plastic deformation of the compliant insert 104 caused by direct contact between compliant insert 104 and the pins 110. In some examples, the interface plate 106 is absent. The example interface plate 106 is described in additional detail below in conjunction with FIG. 2.

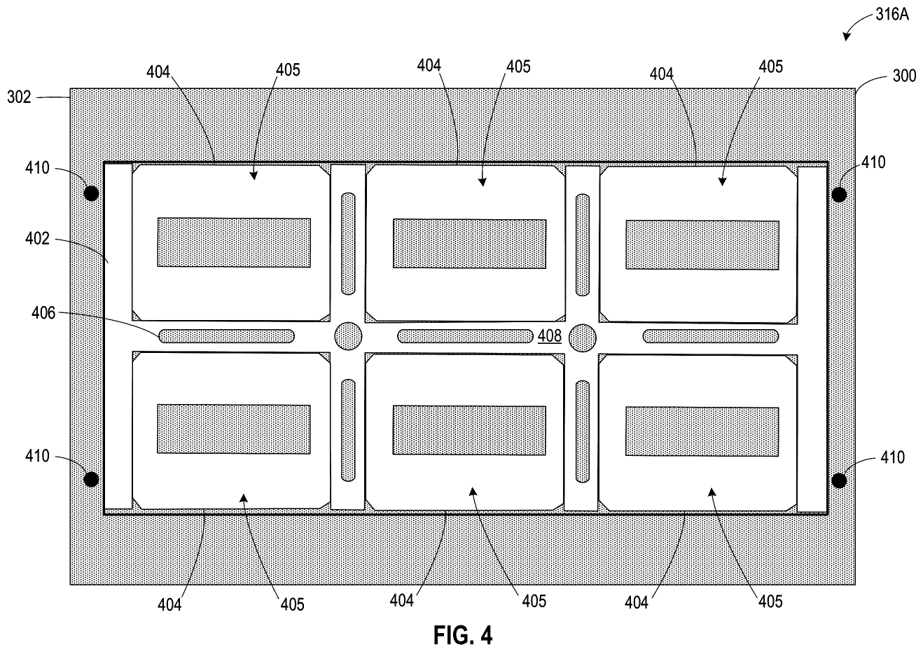

The frame 108 is a mechanical structure including walls that divide the assembly 100 into discrete cells (e.g., discrete sections, etc.) (e.g., the frame 108 is means for dividing and/or means for segmenting the assembly 100, etc.). The frame 108 can be composed of any suitable rigid material. For example, the frame 108 can be composed of a metal (e.g., aluminum, stainless steel, cast iron, etc.), a polymer (e.g., a plastic, an organic polymer, etc.), and/or a ceramic material. In some examples, the frame 108 can be composed of a same material as the cover plate 102. In some examples, the frame 108 and the cover plate 102 can be a single integral component. In some examples, the frame 108 can be absent. In some such examples, the assembly 100 is configured to apply flux to a single discrete substrate package. In some examples, the frame 108 can include through holes aligned with the holes 111 of the cover plate 102. An example frame including such through holes is described below in conjunction with FIG. 4.

The frame 108 divides (e.g., segments, etc.) the assembly 100 into an example first cell 112A (e.g., a first section, etc.), an example second cell 112B (e.g., a second section, etc.), an example third cell 112C (e.g., a third section, etc.), and example fourth cell 112D (e.g., a fourth section, etc.), an example fifth cell 112E (e.g., a fifth section, etc.), and an example sixth cell 112F (e.g., a sixth section, etc.). In the illustrated example of FIG. 1, the compliant insert 104, the interface plate 106 and pins 110 are disposed within the first cell 112A. It should be appreciated that the assembly 100 can include compliant inserts, interface plates 106, and pins similar to the compliant insert 104, the interface plate 106, and pins 110, respectively, in some or all of the other cells 112A, 112B, 112C, 112D, 112E, 112F. In some such examples, each of the cells 112A, 112B, 112C, 112D, 112E, 112F can include pins that apply flux to the pads associated with different package substrates (e.g., the first cell 112A applies flux to a first package substrate, the second cell applies flux to a second package substrate, etc.). The example assembly 100 of FIG. 1 includes six cells (e.g., the cells 112A, 112B, 112C, 112D, 112E, 112F, etc.). In other examples, the frame 108 can divide the assembly 100 into any other suitable number of cells (e.g., two cells, four cells, ten cells, etc.). In the illustrated example of FIG. 1, each of the cells 112A, 112B, 112C, 112D, 112E, 112F has a substantially equal area. As used herein, the term “substantially equal” refers to areas that have a percentage difference (e.g., the ratio of the difference between the areas divided by the average of the areas, etc.) is less than 5%. In the illustrated example of FIG. 1, the cells 112A, 112B, 112C, 112D, 112E, 112F have the same shape (e.g., generally rectangular, etc.). In other examples, the cells 112A, 112B, 112C, 112D, 112E, 112F can have any other suitable spatial relationship(s) and/or size(s).

In the illustrated example of FIG. 1, the frame 108 includes an example first intercell channel 114A between the first cell 112A and the second cell 112B, an example second intercell channel 114B between the second cell 112B and the third cell 112C, an example third intercell channel 114C between the third cell 112C and an example fourth cell 112D, an example fourth intercell channel 114D between the fourth cell 112D and the fifth cell 112E, an example fifth intercell channel 114E between the sixth cell 112F and the first cell 112A, an example sixth intercell channel 114F between the fifth cell 112E and the sixth cell 112F, and an example seventh intercell channel 114G between the second cell 112B and the sixth cell 112F. The intercell channels 114A, 114B, 114C, 114D, 114E, 114F, 114G permit the flow of cleaning fluid between the cells 112A, 112B, 112C, 112D, 112E, 112F during the cleaning of the assembly 100. In the illustrated example of FIG. 1, the first intercell channel 114A, the second intercell channel 114B, the fourth intercell channel 114D, and the fifth intercell channel 114E are approximately the same size and shape. In the illustrated example of FIG. 1, the third intercell channel 114C, the sixth intercell channel 114F, and the seventh intercell channel 114G are approximately the same size and shape and are larger than the channels 114A, 114B, 114C, 114D. In other examples, the channels 114A, 114B, 114C, 114D, 114E, 114F, 114G can have any other suitable size(s) and/or shape(s).

In the illustrated example of FIG. 1, the frame 108 also includes an example first perimeter channel 116A, an example second perimeter channel 116B, an example third perimeter channel 116C, and an example fourth perimeter channel 116D. In the illustrated example of FIG. 1, the perimeter channels 116A, 116B, 116C, 116D facilitate the flow of cleaning fluid from respective ones of the first cell 112A, the third cell 112C, the fourth cell 112D, and the sixth cell 112F out of the assembly 100. In some examples, the perimeter channels 116A, 116B, 116C, 116D can be aligned with openings of a tooling rig in which the assembly 100 is disposed. In the illustrated example of FIG. 1, the perimeter channels 116A, 116B, 116C, 116D are the same size and shape and are smaller than the intercell channels 114A, 114B, 114C, 114D, 114E, 114F, 114G. In other examples, the perimeter channels 116A, 116B, 116C, 116D can have any other suitable size(s) and/or shape(s). In the illustrated example of FIG. 1, the first perimeter channel 116A and the second perimeter channel 116B are aligned with the first intercell channel 114A and the second intercell channel 114B and the third perimeter channel 116C and the fourth perimeter channel 116D are aligned with the fourth intercell channel 114D and the fifth intercell channel 114E.

In the illustrated example of FIG. 1, the intercell channels 114A, 114B, 114C, 114D, 114E, 114F, 114G and the perimeter channels 116A, 116B, 116C, 116D are flat-walled. In other examples, some or all of the channels can be filleted and/or chamfered. Additionally or alternatively, some or all of the intercell channels 114A, 114B, 114C, 114D, 114E, 114F, 114G, and the perimeter channels 116A, 116B, 116C, 116D can be implemented by through holes formed in the walls of the frame 108. In other examples, some or all of the intercell channels 114A, 114B, 114C, 114D, 114E, 114F, 114G and the perimeter channels 116A, 116B, 116C, 116D can be absent. In some examples, the intercell channels 114A, 114B, 114C, 114D, 114E, 114F, 114G and the perimeter channels 116A, 116B, 116C, 116D are means for guiding cleaning fluid through the assembly 100.

The pins 110 are mechanical devices that receive flux and transfer the flux to the pads of a package substrate (e.g., the pins 110 are means for transferring flux, etc.). In the illustrated example of FIG. 1, the pins 110 abut the interface plate 106. In other examples, if the interface plate 106 is absent, the pins 110 abut the complaint insert 104. During operation, the tips of the pins 110 are dipped in a flux material and then applied to the pad of a package substrate prior to the deposition of the solder balls of a BGA. In the illustrated example of FIG. 1, the assembly 100 is segmented into the cells 112A, 112B, 112C, 112D, 112E, 112F. In some such examples, each of the 112A, 112B, 112C, 112D, 112E, 112F can include pins similar to the pins 110. In some such examples, the pins of the assembly 100 can deposit flux on six distinct substrate packages via corresponding ones of the cells 112A, 112B, 112C, 112D, 112E, 112F. It should be appreciated that only a limited number of the pins 110 are illustrated in FIG. 1 for visual clarity. In some examples, the pins 110 are disposed in an array generally corresponding to the interface plate 106.

FIG. 2 is a perspective detailed view of the first cell 112A of the assembly 100 of FIG. 2. In the illustrated example of FIG. 2, the first cell 112A includes the example compliant insert 104 of FIG. 1, the interface plate 106 of FIG. 1 and the pins 110 of FIG. 1. In the illustrated example of FIG. 2, the pins 110 abut a first side of the interface plate 106 and the compliant insert 104 abuts a second side of the interface plate 106 opposite the first side. In the illustrated example of FIG. 2, the cover plate 102 abuts the compliant insert 104 on an opposite side as the interface plate 106.

In the illustrated example of FIG. 2, the interface plate 106 is disposed within the first cell 112A. In the illustrated example of FIG. 2, the interface plate 106 is dimensioned to be smaller than the first cell 112A of the frame 108. That is, in the illustrated example of FIG. 2, an example gap 200 exists between an example edge 201 of the interface plate 106 and the frame 108. In some examples, the gap 200 facilitates the bending of the interface plate 106 near the edge of the interface plate 106, which enables the transfer of flux material by pins disposed near the edge 201 of the interface plate 106 to substrate packages with high amounts of warpage near the edge 201. In other examples, the gap 200 can be absent and some or all of the edge 201 abuts the frame 108.

In the illustrated example of FIG. 2, the interface plate 106 includes an example cutout 202. In the illustrated example of FIG. 2, the cutout 202 is a through hole formed in the center of the interface plate 106. In other examples, the cutout 202 can be a blind hole and/or an area of thinner material. In the illustrated example of FIG. 2, the cutout 202 of FIG. 2 corresponds to a portion of the cell 112A that does not include pins 110. In other examples, some or all of the pins 110 can abut the compliant insert 104 via the cutout 202. In some examples, the interface plate 106 can include any additional number of cutouts (e.g., 2 cutouts, 3 cutouts, etc.). In some examples, the cutout 202 can correspond to a portion of the package substrate including a landside component (LSC). In some examples, the compliant insert 104 can include one or more cutouts (e.g., through holes, blind holes, etc.) that correspond to the cutout 202. In other examples, the cutout 202 is absent. In some such examples, the interface plate 106 can be a continuous planar sheet. In some such examples, the portion of the interface plate 106 corresponding to the package substrate including a landside component (LSC) does not abut the corresponding portion of the interface plate 106.

In the illustrated example of FIG. 2, each of the pins 110 includes a corresponding one of the example lips 204 (e.g., shoulder, flange, etc.) and a corresponding one of the tips 206. In the illustrated example of FIG. 2, the tips 206 of each of the pins 110 are angled at 30 degrees. In other examples, some or all of the pins 110 can have tips that are angled between 30 degrees and 60 degrees relative to the base of the pins 110. The lips 204 are flanges of the pins 110. In some examples, the lips 204 enable the tip 206 of each of the pins 110 to extend through corresponding openings in a tooling rig (e.g., the tooling rig 300 of FIG. 3, etc.) while the lips 204 and the other components of the assembly 100 are retained therein. In some such examples, the lips 204 abut an interior surface of the tooling rig 300, which retains the pins 110 therein.

FIG. 3A is a bottom view of an example tooling rig 300 that can receive one or more of the assembly 100 of FIGS. 1 and/or 2. FIG. 3B is a top view of the tooling rig 300 of FIG. 3A. FIG. 3C is a side view of the tooling rig 300 of FIG. 3A. In the illustrated example of FIG. 3A, the tooling rig 300 includes an example body 302 including an example boss 304 extending from an example bottom face 306 of the body 302. The example boss 304 has an example pin face 308. In the illustrated example of FIG. 3, the pin face 308 includes example first pin orifices 310A, example second pin orifices 310B, example third pin orifices 310C, and example fourth pin orifices 310D. In the illustrated example of FIG. 3C, the boss 304 includes example side openings 312. In the illustrated example of FIG. 3B, the tooling rig 300 includes an example top surface 314 having an example first cavity 316A, an example second cavity 316B, an example third cavity 316C, and an example fourth cavity 316D. In the illustrated example of FIGS. 3A and 3B, an example first assembly 318A, an example second assembly 318B, an example third assembly 318C, and an example fourth assembly 318D, are disposed in the cavities 316A, 316B, 316C, 316D, respectively. In the illustrated example of FIG. 3A, the assemblies 318A, 318B, 318C, 318D include an example first pin array 320A, an example second pin array 320B, an example third pin array 320C, and an example fourth pin array 320D, respectively.

The tooling rig 300, also referred to as a collateral, is a device that can be used to transfer flux from a flux source to a plurality of package substrate during the fabrication of ball grid arrays during second level interconnect manufacturing. In the illustrated example of FIGS. 3A-3C, the tooling rig 300 is configured to receive and support four pin assemblies (e.g., the 318A, 318B, 318C, 318D, etc.), which each include six cells (e.g., cells similar to the cells 112A, 112B, 112C, 112D, 112E, 112F of FIG. 1, etc.). In some such examples, the tooling rig 300 can transfer flux to 24 discrete package substrates. In other examples, depending on the number of cavities and/or the number of cells associated with each assembly, the tooling rig 300 can transfer flux to any suitable number of package substrates.

The assemblies 318A, 318B, 318C, 318D are compliant pin assemblies implemented in accordance with the teachings of this disclosure. For example, some or all of the assemblies 318A, 318B, 318C, 318D can include one or more compliant inserts (e.g., flexible inserts similar to the compliant insert 104 of FIGS. 1 and 2, etc.) and/or one or more interface plates (e.g., interface plates similar to the interface plate 106 of FIGS. 1 and 2, etc.). Some or all of the assemblies 318A, 318B, 318C, 318D can be implemented by the assembly 100 of FIGS. 1 and 2. In some such examples, the pin arrays 320A, 320B, 320C, 320D can correspond to the pins 110 of the assembly 100.

In the illustrated example of FIG. 3B, the assemblies 318A, 318B, 318C, 318D are retained within the cavities 316A, 316B, 316C, 316D via example first fasteners 322A, example second fasteners 322B, example third fasteners 322C, and example fourth fasteners 322D, respectively. In the illustrated example of FIG. 3B, the fasteners 322A, 322B, 322C, 322D extend through respective one of an example first cover plate 324A, an example second cover plate 324B, an example third cover plate 324C, an example fourth cover plate 324D, and an example fourth cover plate 324D. The example cover plates 324A, 324B, 324C, 324D are components of the assemblies 318A, 318B, 318C, 318D, respectively. In the illustrated example of FIG. 3, the cover plates 324A, 324B, 324C, 324D do not include cutouts (e.g., through holes, etc.) similar to the holes 111 of FIG. 11. In some such examples, some or all of the cover plates 324A, 324B, 324C, 324D can be implemented by the assembly 100 of FIG. 1. In other examples, some or all of the cover plates 324A, 324B, 324C, 324D do not include cutouts.

In some examples, the tightening of the fasteners 322A, 322B, 322C, 322D compresses the components of the assemblies 318A, 318B, 318C, 318D to compress and causes the compliant inserts of the assemblies 318A, 318B, 318C, 318D to be preloaded. In the illustrated example of FIG. 3B, the fasteners 322A, 322B, 322C, 322D are screws. In other examples, the fasteners 322A, 322B, 322C, 322D can be implemented by any suitable type of fasteners. In some examples, some of all of the fasteners 322A, 322B, 322C, 322D can be absent. In some such examples, the assemblies 318A, 318B, 318C, 318D can be retained within the cavities 316A, 316B, 316C, 316D via gravity and/or any other suitable fastening techniques (e.g., one or more welds, one or more interference fins, one or more mechanical retention features, one or more chemical adhesives, etc.).

In the illustrated example of FIGS. 3A and 3C, the side openings 312 are formed in the boss 304 adjacent to the pin arrays 320A, 320B, 320C, 320D of corresponding ones of the assemblies 318A, 318B, 318C, 318D. The side openings 312 cause the cavities 316A, 316B, 316C, 316D to be fluidly open to the exterior of the tooling rig 300. In some examples, the side openings 312 enable coolant to flow from inside the cavities 316A, 316B, 316C, 316D to the exterior of the tooling rig 300. In some such examples, the side openings 312 of the tooling rig 300 can be aligned with perimeter channels of a frame of some or all of the assemblies 318A, 318B, 318C, 318D (e.g., the perimeter channel 116A, 116B, 116C, 116D of the frame 108 of FIG. 1, etc.). In some such examples, the side openings 312 enable cleaning fluid to flow into and/or out of the assemblies 318A, 318B, 318C, 318D during the cleaning thereof.

During operation, the assemblies 318A, 318B, 318C, 318D are disposed within the tooling rig 300 such the pin arrays 320A, 320B, 320C, 320D of each of the assemblies 318A, 318B, 318C, 318D extend through corresponding ones of the pin orifices 310A, 310B, 310C, 310D. In some examples, the tooling rig 300 is loaded onto an automated fabrication machine and/or ball placement system such that the pin face 308 is oriented towards the ground. In some such examples, a flux source and a plurality of package substrates can be disposed within the machine. The tooling rig 300 can then be moved by the ball placement system such that the pin arrays 320A, 320B, 320C, 320D are dipped into the flux of the flux source and positioned over the package substrates. In some examples, the tooling rig 300 can then be pressed downward by the system until the pin arrays 320A, 320B, 320C, 320D contact one or more package substrates and transfer flux and/or solder thereto.

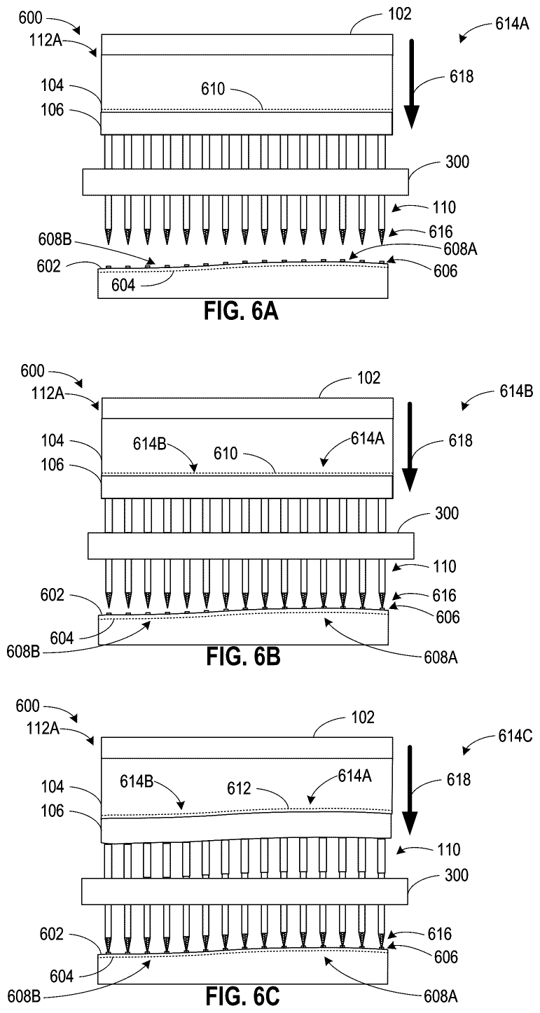

The deposition of flux by the tooling rig 300 and the compliance of the compliant insert 104 and the interface plate 106 are described below in conjunction with FIGS. 6A-6C. After the deposition of the flux by the pin arrays 320A, 320B, 320C, 320D of the tooling rig 300, solder balls of a BGA can be placed on the plurality of package substrates. In some such examples, the solder of BGA can be deposited by the pin arrays 320A, 320B, 320C, 320D of the tooling rig 300. In other examples, the solder balls can be disposed on the package substrate by any other suitable device.

FIG. 4 is a top detail view of a first assembly 318A of FIGS. 3A-3C, in which the first plate cover plate 324A of FIG. 3B and complaint inserts have been removed. In the illustrated of FIG. 4, the first assembly 318A includes an example frame 402 and a plurality of example interface plates 404. In some examples, the frame 402 can be implemented by the frame 108 of FIG. 1 and/or some or all of the interface plates 404 can be implemented by the interface plate 106. In some examples, some or all of the other assemblies of FIG. 3A-3C (e.g., the second assembly 318B, the third assembly 318C, and the fourth assembly 318D, etc.) can include a frame similar to the frame 402 and/or interface plates similar to the plurality of interface plates 404. In some examples, the frame 108 can be fixedly coupled to the first cavity 316A of the tooling rig 300. In some examples, the frame 108 can be integral with the tooling rig 300. In the illustrated example of FIG. 4, the tooling rig 300 includes dot stippling for visual clarity purposes only.

In the illustrated example of FIG. 4, the example frame 402 divides the first assembly 318A into a plurality of example cells 405 (e.g., cells similar to the cells 112A, 112B, 112C, 112D, 112E, 112F of FIG. 1, etc.). In the illustrated example of FIG. 4, each of the cells 405 are of a same size and shape, which are defined by the walls of the frame 402 and the interior walls of the first cavity 316A. In other examples, some or all of the cells 405 can be different sizes and/or shapes.

In the illustrated example of FIG. 4, the example frame 402 includes example holes 406 disposed on an example top surface 408 of the frame 402. The example holes 406 permit the flow of coolant fluid through frame 108 during the cleaning of the assembly. In other examples, some or all of the holes 406 can be absent. In some examples, the frame 402 can include channels similar to some or all of the channels 114A, 114B, 114C, 114D, 114E, 114F, 114G, 116A, 116B, 116C, 116D of the frame 108 of FIG. 1. In some examples, such channels 114A, 114B, 114C, 114D, 114E, 114F, 114G, 116A, 116B, 116C, 116D are in fluid communication with the holes 406 shown in FIG. 4.

In the illustrated example of FIG. 4, ones of the plurality of interface plates 404 are disposed within corresponding ones of the cells 405 and abut (e.g., rest upon) associated ones of the pins of the first pin array 320A (not visible in FIG. 4). In the illustrated example of FIG. 4, the interface plates 404 have a smaller planar area than the corresponding ones of the interface plates 404. In some such examples, the smaller size of the interface plates 404 causes the interface plates 404 to sit loosely within the cells 405. In some such examples, the loose seating of the interface plates 404 enables the interface plates 404 to flex to facilitate the deposition of flux on warped package substrates. In the illustrated example of FIG. 4, gaps (e.g., gaps similar to the gap 200 of FIG. 2, etc.) separate the interface plate 404 from the walls of the frame 402 and the tooling rig 300.

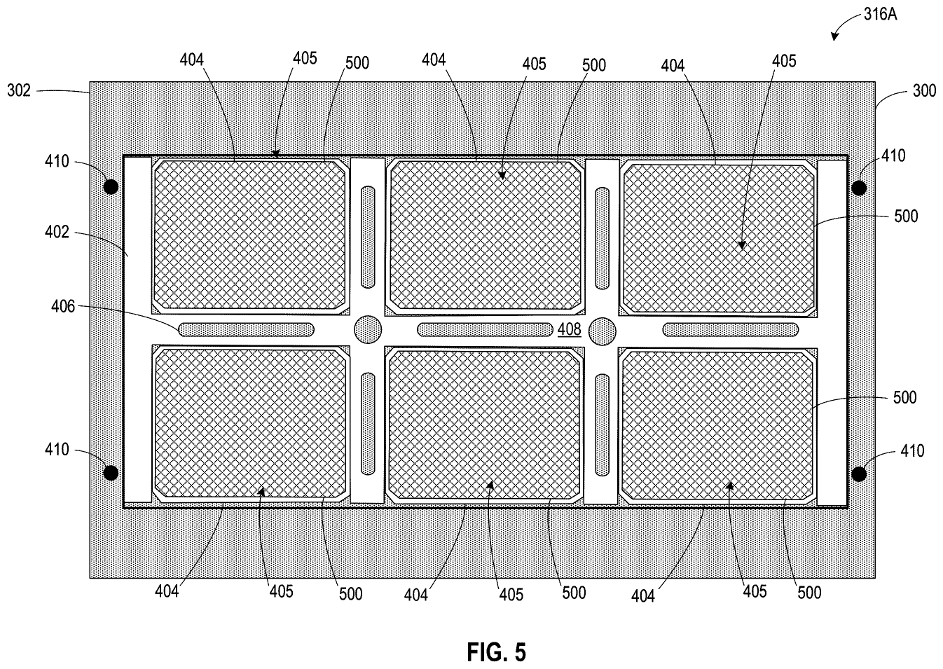

In the illustrated example of FIG. 4, the tooling rig 300 includes examples holes 410. In some examples, the holes 410 enable a cover plate (e.g., the first cover plate 324A of FIGS. 3A-3C, etc.) of the first assembly 318A to be coupled to the tooling rig 300 (after the placement of compliant inserts on the interface plates 404 as discussed below in connection with FIG. 5). For example, the holes 410 can receive corresponding ones of the fasteners 322A of FIG. 3B. In other examples, some or all of the holes 410 can be absent.

FIG. 5 is a top detail of a first assembly 318A of FIG. 4 after the deposition of example compliant inserts 500 within corresponding ones of the cells 405. In some examples, some or all of the compliant inserts 500 can be implemented by the compliant insert 104 of FIGS. 1 and 2. In the illustrated example of FIG. 5, the tooling rig 300 includes dot stippling and the compliant inserts include hatching for visual clarity purposes only.

In the illustrated example of FIG. 5, the compliant inserts 500 are in an unloaded state with a corresponding unloaded thickness. In the illustrated example of FIG. 5, the compliant inserts 500 are not flush with the top surface 408 of the frame 402 and the top surface of the boss 304 (e.g., the unloaded thickness of the compliant inserts 500 extends beyond the top surface 408 of the frame 402, etc.). In the illustrated example of FIG. 5, the compliant inserts 500 extend past the top surface 314 of the tooling rig 300. In some such examples, when the cover plate 324A is coupled to the first assembly 318A and/or tooling rig 300, the cover plate 324A compresses and preloads the compliant inserts 500 (e.g., the cover plate 324A is means for retaining the complaint inserts 500 in a preloaded position, etc.). In such examples, the unloaded thickness of the compliant inserts 500 is greater than the distance between the cover plate 324A and corresponding ones of the interface plates 404. In some examples, the loaded thickness of the compliant inserts 500 corresponds to the distance between the cover plate 324A and corresponding ones of the interface plates 404.

In some such examples, the preload of the compliant inserts 500 increases the spring force exerted by the first assembly 318A during the deposition of the flux via the pins of the first assembly 318A, which increases the likelihood flux will be deposited on the pads in warped region(s) of the package substrate(s). In some examples, the compliant inserts 500 can be flush with the top surface 408 of the frame 402 and/or have any other suitable size.

FIGS. 6A-6C are schematic illustrations of an operation to deposit flux on an example package substrate 602 of an example portion 600 of the first cell 112A of the assembly 100 of FIG. 1. In the illustrated example of FIGS. 6A-6C, the example portion 600 includes the example compliant insert 104, the example interface plate 106, and the example pins 110. In the illustrated example of FIGS. 6A-6C, the pins 110 of the portion 600 is in contact with an example package substrate 602, which has an example warpage profile 604 and includes example pads 606. In the illustrated example of FIGS. 6A-6C, the warpage profile 604 of the package substrate 602 includes an example elevated region 608A and an example depressed region 608B.

In the illustrated example of FIG. 6A, the portion 600 is in a first position 614A prior to contact with a package substrate 602. In the illustrated example of FIG. 6B, the portion 600 is in an example second position 614B after the pins 110 have contacted the pads 606 in the elevated region 608A. In the illustrated example of FIG. 6C, the portion 600 is in an example third position 614C after the pins 110 have contacted the pads 606 in the depressed region 608B. In the illustrated example of FIGS. 6A and 6B, the compliant insert 104 and the example interface plate 106 has an example precontact profile 610. In the illustrated example of FIG. 6C, the contact between the pins 110 and the substrate package causes the compliant insert 104 and the example interface plate 106 to assume an example loaded profile 612 (e.g., a compression profile, etc.), having an example first region 614A and an example second region 614B.

The package substrate 602 is the main structural component of an integrated circuit package that enables the connection between an integrated circuit (e.g., a die mounted to an opposite side of the package substrate, etc.) and a printed circuit board (PCB). In some examples, the package substrate 602 can be a glass-cored substrate and/or a coreless package substrate. In other examples, the package substrate 602 can be implemented by any suitable type of substrate. In the illustrated example of FIGS. 6A-6C, the package substrate 602 includes the pads 606, which are the pads of a ball grid array. In some such examples, the pads 606 can receive solder balls, which can form a second level interconnect (SLI) between the package substrate 602 and a printed circuit board. In the illustrated example of FIGS. 6A-6C, the package substrate 602 has the warpage profile 604. In some examples, the warpage profile 604 is formed in the package substrate 602 during the manufacturing of the package substrate 602 and/or the assembly of one or more integrated circuits thereon. For example, if the package substrate 602 is composed of multiple components having different coefficients of thermal expansion (CTE), thermal changes can cause components of the package substrate 602 to expand/contract at different rates, which can cause the package substrate 602 to assume the warpage profile 604 at different temperatures. In some such examples, material and/or manufacturing variations can cause the warpage profile 604 to vary between different instances of the package substrate 602. In the illustrated example of FIGS. 6A-6C, the warpage profile 604 causes the package substrate to have the elevated region 608A and the depressed region 608B. In some examples, the warpage profile 604 can cause the substrate packages to have multiple elevated portion and/or depressed portions in addition to the elevated region 608A and the depressed region 608B.

In the illustrated example of FIGS. 6A-6C, the pins 110 include example flux 616, which is being deposited on the example pads 606 by pressing the pins 110 against the pads 606 of the package substrate 602 via an example force 618. The example flux 616 is an adhesive substance that forms an adhesive interface between the pads 606 and soldering balls of a BGA to be positioned thereon. In some examples, the flux 616 is a liquid, a powder, and/or a paste. The flux 616 can be made of any suitable adhesive material, including a rosin flux (e.g., a resin flux, solid rosin flux, reduced solids rosin flux, etc.), a low-solid flux (e.g., an alcohol-based flux, a water-based flux, etc.), a water-soluble flux (e.g., a halide activated flux, a halide free flux, etc.), an organic flux, an inorganic flux, and/or any other suitable type of flux. In some examples, if the flux 616 is not deposited on the pads 606, soldering balls will not adhere to the pads 606, which can lead to the package substrate 602, needing to be reprocessed, rejected, and/or scraped.

The example force 618 can be applied to a tooling rig containing the portion 600 (e.g., the tooling rig 300 of FIGS. 3A-3C, etc.). In some such examples, the force 618 can be applied by a fabricator and/or ball transfer system in which the tooling rig is associated. The force 618 causes the portion 600 to translate downward until some or all of the tips 206 contact the pads 606. In the illustrated example of FIGS. 6A-6C, when the tips 206 of the pins 110 contact the pads 606, the flux 616 is transferred from the tips 206 of the pins 110 to the pads 606.

In the illustrated example of FIG. 6A, in the first state 614A, the force 618 causes the portion 600 to translate toward the package substrate 602. In the illustrated example of FIG. 6B, in the second state 614B, the force 618 is causing some of the pins 110 in the first region 614A to contact the pads 606 of the elevated region 608A and transfer the flux 616 thereto. In the illustrated example of FIG. 6C, in the third state 614C, the other ones of the pins 110 continued to move towards the package substrate 602, the compliant insert 104 compresses bends in the first region 614A and the interface plate 106 bends in the first region 614A due to reaction force caused by the abutment of some of the pins 110 and the package substrate 602 in the elevated region 608A (e.g., the compliant insert 104 is a means for adjusting a profile of the pins 110, the interface plate 106 is a means for adjusting a profile of the pins 110, etc.) In the illustrated example of FIG. 6C, the force 618 has caused the portion 600 to continue to translate downward until the pins 110 contact the pads 606 into the depressed region 608B and transfer the flux 616 thereto. In the illustrated example of FIG. 6C, the elastic deformation of the compliant insert 104 and interface plate 106 causes the portion 600 (e.g. the compliant insert 104 and interface plate 106, etc.) to assume the load profile 612, which corresponds to and is complimentary with the warpage profile 612 of the package substrate 602. That is, the first region 614A of the loaded profile 612 is elastically deformed by the contact of the pins 110 and the pads 606 of the elevated region 608A, such that the second region 614B is able to contact the pads 606 of the depressed region 608B. It should be appreciated that the elasticity and compliance of the compliant insert 104 and/or interface plate 106 enables the portion 600 to assume any profile based on the warpage profile of the substrate package to which the flux 616 is being transferred. As such, the compliant insert 104 and interface plate 106 ensure the flux 616 is transferred to the pads 606 of the package substrate 602 regardless of the warpage thereof.

In some examples, after the flux 616 has been transferred to each of the pads 606 by the pins 110, the portion 600 can be retracted from the package substrate 602. In some such examples, because the interface plate 106 is composed of a strong resilient elastic material (e.g., stainless steel, aluminum, etc.) and/or the compliant insert 104 is composed of flexible compliant material (e.g., silicon foam, etc.), the release of the compressive force caused by the abutment of the pins 110 and the elevated region 608A causes the portion 600 to return from the loaded profile 612 to the precontact profile 610 (e.g., the position of the first state 614A and the second state 614B, etc.). In some such examples, if the compliant insert 104 is preloaded, the spring force (e.g., the release of strain from the portion 600, etc.) is increased (e.g., augmented, etc.) by the compliant insert 104. In some examples, because the flux 616 is typically an adhesive substance, the portion 600 can be cleaned (e.g., via cleaning fluid, etc.) to remove excess flux from the pins 110, the interface plate 106, and/or the compliant insert 104.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

Compliant inserts for pin dipping processes are disclosed herein. Further examples and combinations thereof include the following:

Example methods, apparatus, systems, and articles of manufacture for compliant inserts for pin dipping processes are disclosed herein. Further examples and combinations thereof include the following:

Example 1 includes an apparatus comprising a pin array to transfer material to a package substrate of an integrated circuit package, and a cover plate, and an elastic insert to be disposed between the cover plate and the pin array.

Example 2 includes the apparatus of example 1, wherein the cover plate includes a through hole.

Example 3 includes the apparatus of example 1, further including an interface plate disposed between the elastic insert and the pin array.

Example 4 includes the apparatus of example 3, wherein the interface plate includes a through hole.

Example 5 includes the apparatus of example 4, wherein the through hole has a shape corresponding to a landside component of the integrated circuit package.

Example 6 includes the apparatus of example 3, wherein the interface plate is composed of stainless steel and has a thickness between 50 micrometers and 150 micrometers.

Example 7 includes the apparatus of example 3, wherein the interface plate is to abut a first side of the elastic insert and the cover plate to abut a second side of the elastic insert, the second side opposite the first side.

Example 8 includes the apparatus of example 7, wherein the elastic insert has an unloaded thickness greater than a distance between the interface plate and the cover plate.

Example 9 includes the apparatus of example 7, further including a frame defining a plurality of cells including a first cell, and wherein the pin array, compliant insert, and the interface plate are disposed within the first cell.

Example 10 includes the apparatus of example 9, wherein the interface plate is a first interface plate, the elastic insert is a first elastic insert, the pin array is a first pin array, and the apparatus further includes a second pin array disposed in a second cell of the plurality of cells, a second interface plate disposed in the second cell, and a second compliant insert disposed in the second cell.

Example 11 includes the apparatus of example 10, wherein the first elastic insert is distinct and separate from the second elastic insert.

Example 12 includes the apparatus of example 10, wherein the first cell and the second cell have a substantially equal area.

Example 13 includes the apparatus of example 1, further including a tooling rig, wherein the pin array includes a pin having a flange, the flange to abut an interior surface of the tooling rig.

Example 14 includes the apparatus of example 1, wherein (1) the pin array includes first pins and second pins and (2) the elastic insert is configured to elastically compress into a loaded profile to enable the first pins to abut an elevated region of the package substrate and the second pins to abut a depressed region of the package substrate.

Example 15 includes the apparatus of example 1, wherein the elastic insert is composed of silicone foam.

Example 16 includes an apparatus comprising means for transferring flux to a pad of an integrated circuit package, and means for adjusting a profile of the means for transferring flux.

Example 17 includes the apparatus of example 16, further including means for interfacing the transferring means with the adjusting means, the interfacing means disposed between the transferring means and the adjusting means.

Example 18 includes the apparatus of example 17, further including a means for retaining the adjusting means in a compressed state.

Example 19 includes the apparatus of example 16, further including a means for dividing a first section from a second section, the transferring means and the adjusting means to be disposed within the first section.

Example 20 includes the apparatus of example 19, wherein the dividing means includes means for guiding a cleaning fluid through the apparatus.

Example 21 includes an apparatus comprising an array of pins, the pins having first ends and second ends opposite the first ends, the first ends of the pins to transfer flux to pads on an integrated circuit package, and a compliant insert to be positioned adjacent the second ends of the pins.

Example 22 includes the apparatus of example 21, further including a tooling rig to support the pins.

Example 23 includes the apparatus of example 21, wherein the second ends of the pins abut the compliant insert.

Example 24 includes the apparatus of example 22, further including an interface plate disposed between the complaint insert and the array of pins, the second ends of the pins abutting the compliant insert.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
a pin array to transfer material to a package substrate of an integrated circuit package; and
a cover plate; and
an elastic insert to be disposed between the cover plate and the pin array.

2. The apparatus of claim 1, wherein the cover plate includes a through hole.

3. The apparatus of claim 1, further including an interface plate disposed between the elastic insert and the pin array.

4. The apparatus of claim 3, wherein the interface plate includes a through hole.

5. (canceled)

6. (canceled)

7. The apparatus of claim 3, wherein the interface plate is to abut a first side of the elastic insert and the cover plate to abut a second side of the elastic insert, the second side opposite the first side.

8. The apparatus of claim 7, wherein the elastic insert has an unloaded thickness greater than a distance between the interface plate and the cover plate.

9. The apparatus of claim 7, further including a frame defining a plurality of cells including a first cell, and wherein the pin array, compliant insert, and the interface plate are disposed within the first cell.

10. The apparatus of claim 9, wherein the interface plate is a first interface plate, the elastic insert is a first elastic insert, the pin array is a first pin array, and the apparatus further includes:
a second pin array disposed in a second cell of the plurality of cells;
a second interface plate disposed in the second cell; and
a second compliant insert disposed in the second cell.

11. The apparatus of claim 10, wherein the first elastic insert is distinct and separate from the second elastic insert.

12. (canceled)

13. The apparatus of claim 1, further including a tooling rig, wherein the pin array includes a pin having a flange, the flange to abut an interior surface of the tooling rig.

14. The apparatus of claim 1, wherein (1) the pin array includes first pins and second pins and (2) the elastic insert is configured to elastically compress into a loaded profile to enable the first pins to abut an elevated region of the package substrate and the second pins to abut a depressed region of the package substrate.

15. (canceled)

16. An apparatus comprising:
means for transferring flux to a pad of an integrated circuit package; and
means for adjusting a profile of the means for transferring flux.

17. The apparatus of claim 16, further including means for interfacing the transferring means with the adjusting means, the interfacing means disposed between the transferring means and the adjusting means.

18. The apparatus of claim 17, further including a means for retaining the adjusting means in a compressed state.

19. The apparatus of claim 16, further including a means for dividing a first section from a second section, the transferring means and the adjusting means to be disposed within the first section.

20. The apparatus of claim 19, wherein the dividing means includes means for guiding a cleaning fluid through the apparatus.

21. An apparatus comprising:
an array of pins, the pins having first ends and second ends opposite the first ends, the first ends of the pins to transfer flux to pads on an integrated circuit package; and
a compliant insert to be positioned adjacent the second ends of the pins.

22. The apparatus of claim 21, further including a tooling rig to support the pins.

23. The apparatus of claim 21, wherein the second ends of the pins abut the compliant insert.

24. The apparatus of claim 22, further including an interface plate disposed between the complaint insert and the array of pins, the second ends of the pins abutting the compliant insert.
